(19) United States
(12) Patent Application Publication
(10) Pub. No.: US 2026/0090413 A1
(43) Pub. Date: Mar. 26, 2026

(54) PACKAGE WITH SIDE-WETTABLE STRUCTURE FORMED ON VIA WALLS

(71) Applicant: PANJIT INTERNATIONAL INC., Kaohsiung City (TW)

(72) Inventors: CHUNG-HSIUNG HO, Kaohsiung City (TW); YUNG-HUI WANG, Kaohsiung City (TW); CHI-HSUEH LI, Tainan City (TW); WEI-TING CHEN, Taoyuan City (TW)

(21) Appl. No.: 18/975,341

(22) Filed: Dec. 10, 2024

(30) Foreign Application Priority Data
Sep. 26, 2024 (TW) 113136686

(51) Int. Cl. H01L 23/498; H01L 23/13; H01L 23/31

(52) U.S. Cl. CPC H10W 70/635; H10W 70/65; H10W 70/68; H10W 74/114

(57) ABSTRACT

A package with a side-wettable structure formed on via walls has a composite substrate covered with a molding layer; an upper redistribution layer is formed on the molding layer, and an edge of the upper redistribution layer is uncovered with a solder mask to form at least one edge bonding surface; at least one conductive contact formed by cutting at least one conductive via is located adjacent to an edge of the composite substrate, and each edge bonding surface is connected with a cutting surface of each conductive contact; an anti-oxidation conductive layer is mounted on each cutting surface and a side wall of each conductive contact. The anti-oxidation conductive layer is adopted for a solder adsorption, so that an Automated Optical Inspection instrument can determine contacting situations between the package of the present invention and another component.

### CROSS REFERENCE TO RELATED APPLICATIONS

The present application claims priority to Taiwan application No. 113136686, filed on Sep. 26, 2024, the content of which is hereby incorporated by reference in its entirety.

### BACKGROUND OF THE INVENTION

### 1. Field of the Invention

The present invention relates to side-wettable semiconductor packing technology, especially a package with a side-wettable structure formed on via walls.

### 2. Description of the Related Art

Through-hole technology (THT) and surface mount technology (SMT) are conventional arts to install a package. The installation by THT is to insert the package's leads into corresponding holes on a circuit board, and then fill the corresponding holes with solder to fix the package on the circuit board. The installation by SMT is to adhere the package's bond pads to corresponding joints on a circuit board by the solder to fix the package on the circuit board. In general, the type of the package using SMT may be a Quad Flat No-Lead (QFN) package, a Dual Flat No-Lead (DFN) package, etc.

The package using SMT usually has a side-wettable structure on sides of the bond pads for facilitating an Automated Optical Inspection (AOI) instrument to determine whether the package is well-soldered to the circuit board according to the solder creepage on the sides of the packages. Referring to FIG. 5, a conventional package 80 has a bottom bond pad 81. The bottom bond pad 81 can be formed by a lead frame and has an indented area 82. The indented area 82 is the side-wettable structure for solder creepage. However, the indented area 82 is prepared in advance on the lead frame before packaging process, or is formed by cutting the lead frame multiple times during the packaging process. That is, the indented area 82 requires relatively more and complicated manufacturing steps, which increases manufacturing cost of the overall package 80. Moreover, a height of the side of the lead frame of the package 80 (the side of the bottom bond pad 81) that can allow the solder to adhere is still not high enough.

### SUMMARY OF THE INVENTION

To overcome the aforementioned issue, the present invention provides a package with a side-wettable structure formed on via walls. The present invention reduces process complexity of the manufacturing process to form a side-wettable structure.

In order to achieve the aforementioned objectives, the package of the present invention comprises:
a composite substrate having a conductive layer on an exterior of the composite substrate and an accommodating space in an interior of the composite substrate;
a die mounted in the accommodating space;
a molding layer covering the composite substrate and filling the accommodating space to wrap the die;
an upper redistribution layer mounted on the molding layer;
a solder mask covering the upper redistribution layer and exposing at least one edge of the upper redistribution layer to form at least one edge bonding surface; and
at least one conductive contact formed by cutting at least one conductive via and located adjacent to at least one edge of the composite substrate, and each conductive contact correspondingly and electrically connected with each edge bonding surface and the conductive layer of the composite substrate respectively;
wherein each conductive contact comprises a cutting surface including a side surface of the upper redistribution layer and connected with the at least one edge bonding surface, and an anti-oxidation conductive layer is mounted on each bonding surface and the cutting surface of each conductive contact.

During manufacturing processes of the package with a side-wettable structure formed on via walls of the present invention, the at least one conductive via connecting with the upper redistribution layer and the conductive layer of the composite substrate is located adjacent to at least one edge of the entire package, so that the at least one conductive via can be cut during the singulation process of the package. The part of each conductive via remaining in the package after cutting is respectively defined as a conductive contact. Since the cutting surface formed by singulation process of each conductive contact exposes a metal layer, the anti-oxidation conductive layer can be plated on the cutting surface of each conductive contact to form the side-wettable structure. Compared with the prior art that the lead frame needs to be pre-processed before the manufacturing processes (or need to be cut multiple times during the manufacturing processes) to form the side-wettable structure, a structural improvement of the package of the present invention can form the side-wettable structure through only one cutting (singulation process), thereby reducing process complexity and saving manufacturing costs.

Moreover, the anti-oxidation conductive layer is adopted for a solder adsorption, and the side surface of each conductive contact can be the anti-oxidation conductive layer to be plated on. The anti-oxidation conductive layer mounted on the surface of each conductive contact increases an area to which the solder adheres when the package of the present invention is soldered to another component, thereby increasing the stability of the package soldered to the circuit board. Moreover, the side surface of the package of the present invention can be adhered with more solder compared with the prior art to improve the inspection capability of the Automated Optical Inspection instrument, so that the present invention has an effect of stabilizing the automated manufacturing process.

### BRIEF DESCRIPTION OF THE DRAWINGS

FIG. 1 is a cross-sectional side view of a composite substrate of the package of the present invention;

FIGS. 2A to 2N are schematic views of packaging processes of a first embodiment of the package of the present invention;

FIG. 2O is a perspective view of the first embodiment of the package of the present invention;

FIG. 2P is a schematic view of application of the first embodiment of the package of the present invention;

FIG. 2P-2 is a schematic view in partial section of application of the first embodiment of the package of the present invention;

FIGS. 3A to 3O are schematic views of packaging processes of a second embodiment of the package of the present invention;

FIG. 3P is a perspective view of the second embodiment of the package of the present invention;

FIG. 3Q is a schematic view of application of the second embodiment of the package of the present invention;

FIG. 3Q-2 is a schematic view in partial section of application of the second embodiment of the package of the present invention;

FIGS. 4A to 4N are schematic views of packaging processes of a third embodiment of the package of the present invention;

FIG. 4O is a perspective view of the third embodiment of the package of the present invention;

FIG. 4P is a schematic view of application of the third embodiment of the package of the present invention;

FIG. 4P-2 is a schematic view in partial section of application of the third embodiment of the package of the present invention;

FIG. 5 is a cross-sectional side view in partial section of a conventional package.

### DETAILED DESCRIPTION OF THE INVENTION

In order to understand the technical characteristics and practical effects of the prevent invention in detail, and accomplish them according to the content of the present invention, the detailed description is as follows with the embodiments shown in the figures.

The present invention is a package with a side-wettable structure formed on via walls, wherein the package can be a Panel-Level-Package (PLP) component. The Panel-Level-Package process refers to a process that uses a substrate as a carrier to package one (or more) die that has gone through a production of integrated circuits. Packaging processes and structure of the package with a side-wettable structure formed on via walls of the present invention are described with figures below.

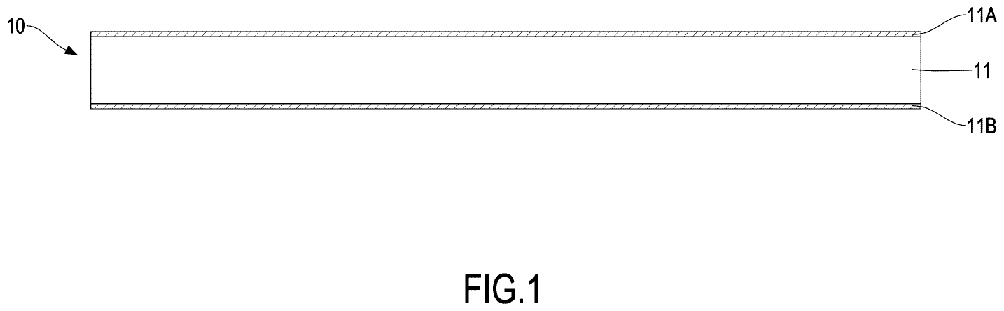

Referring to FIG. 1, FIG. 1 is a cross-sectional view of a composite substrate 10. The composite substrate 10 includes a base layer 11, an upper metal sheet 11A formed on a top surface of the base layer 11, and a lower metal sheet 11B formed on a bottom surface of the base layer 11. For example, the composite substrate 10 can be a copper clad laminate (CCL), that is, the upper metal sheet 11A and the lower metal sheet 11B are respectively a copper foil, and a material of the base layer 11 can be resin.

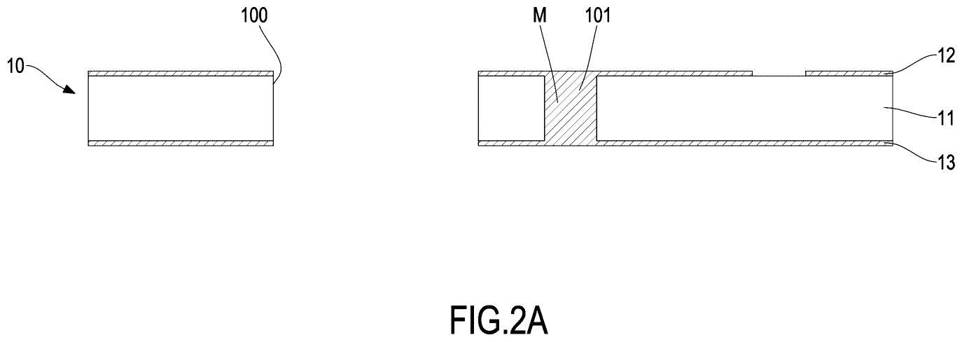

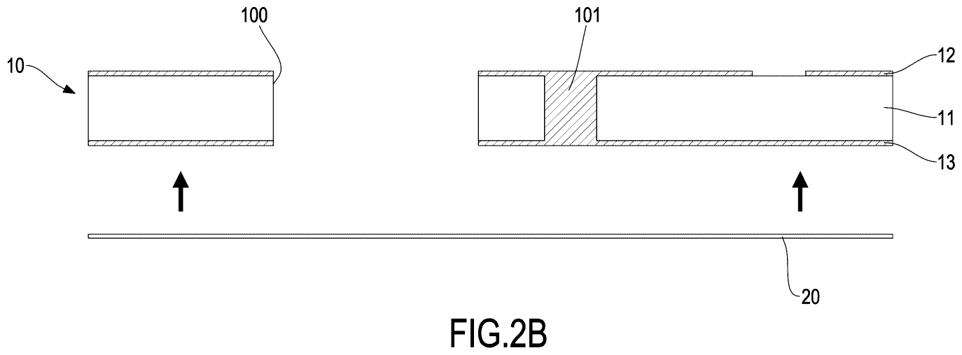

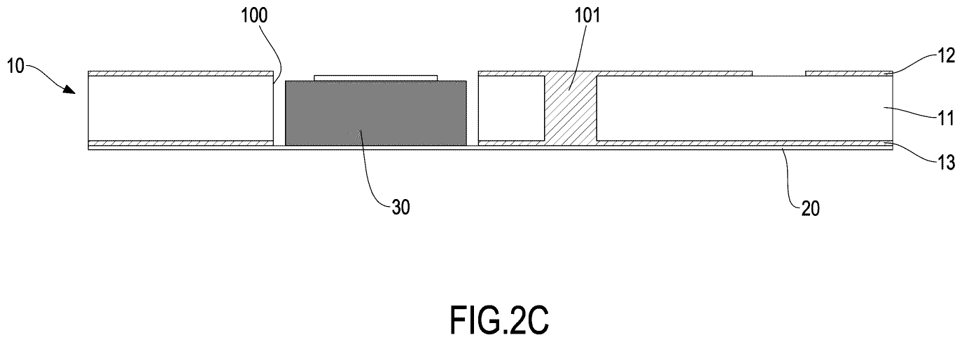

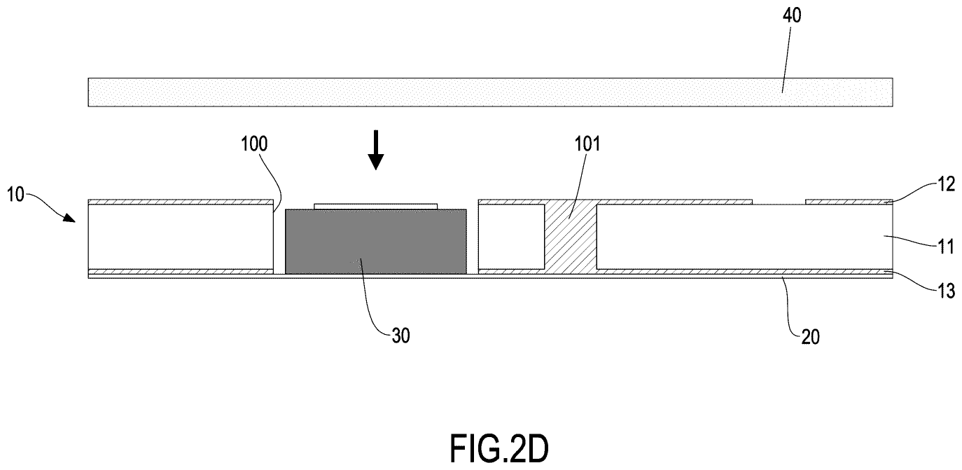

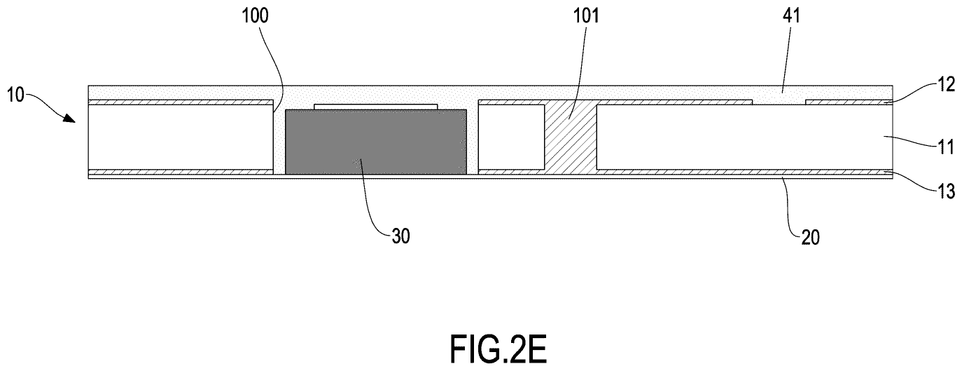

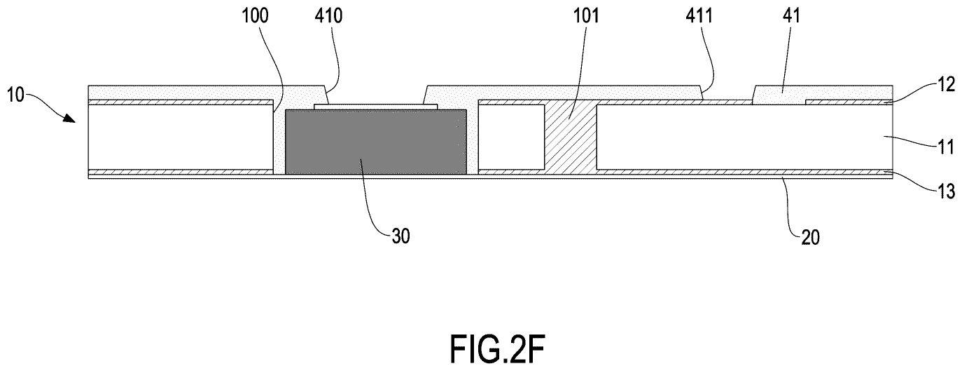

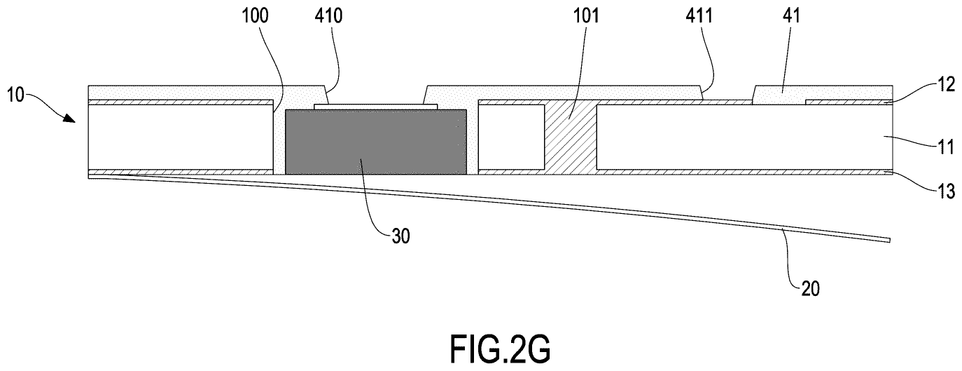

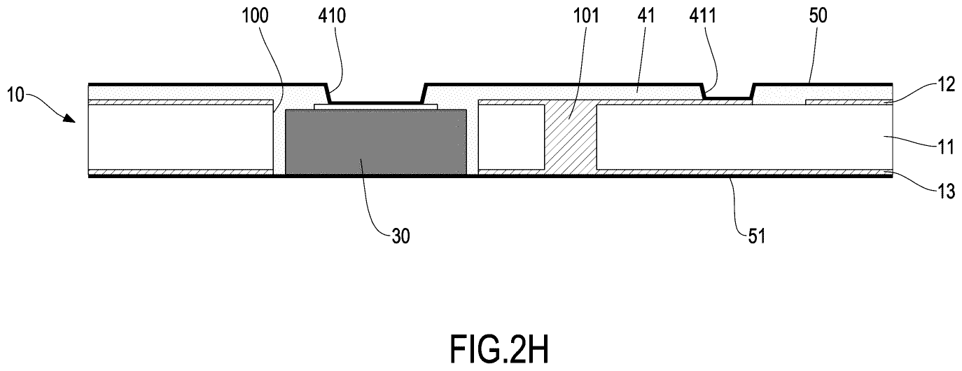

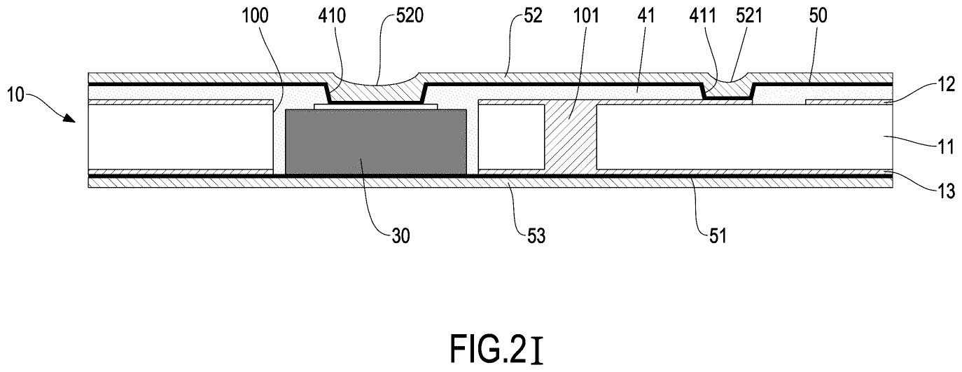

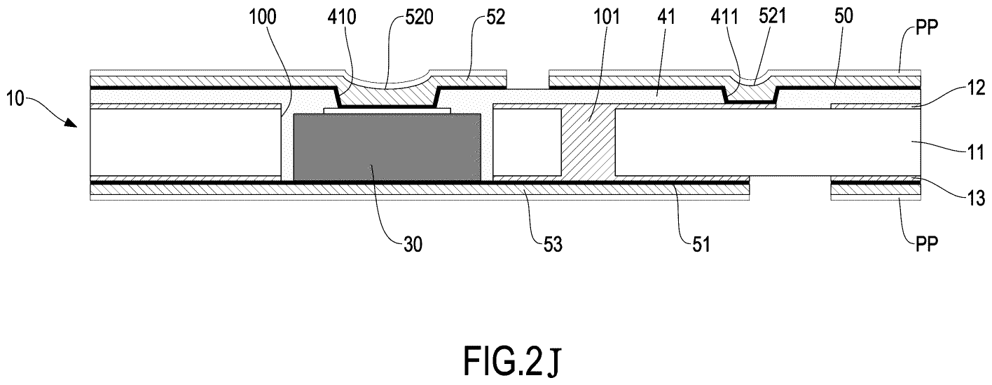

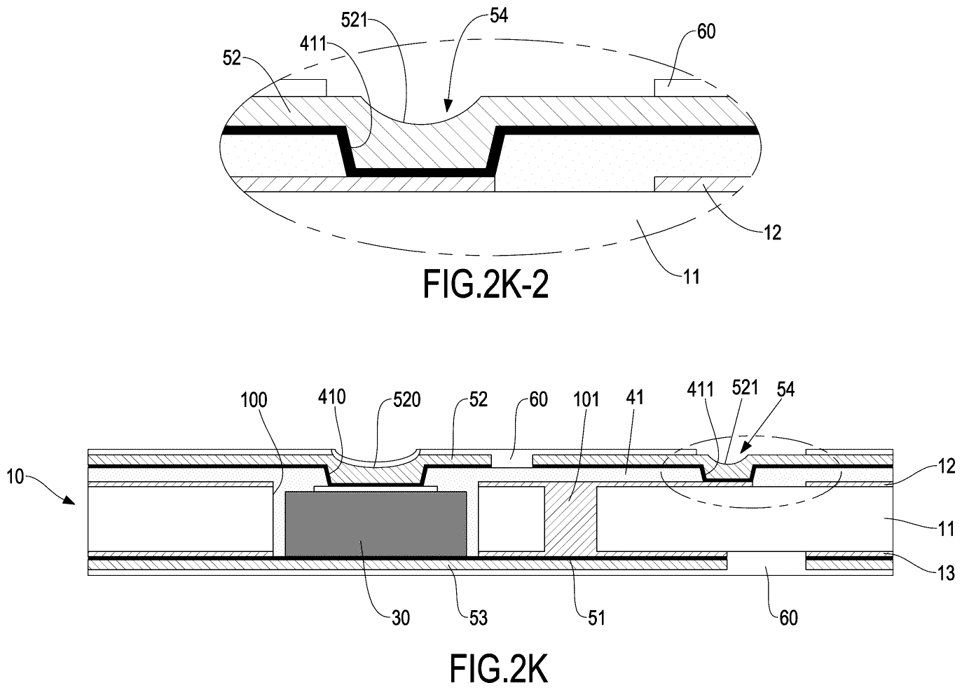

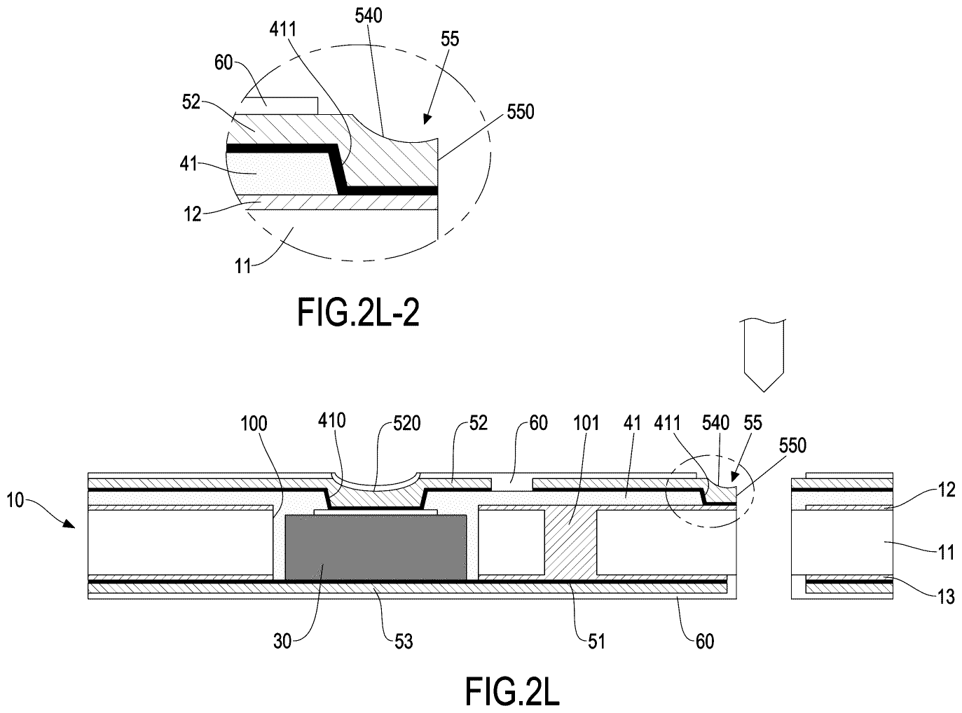

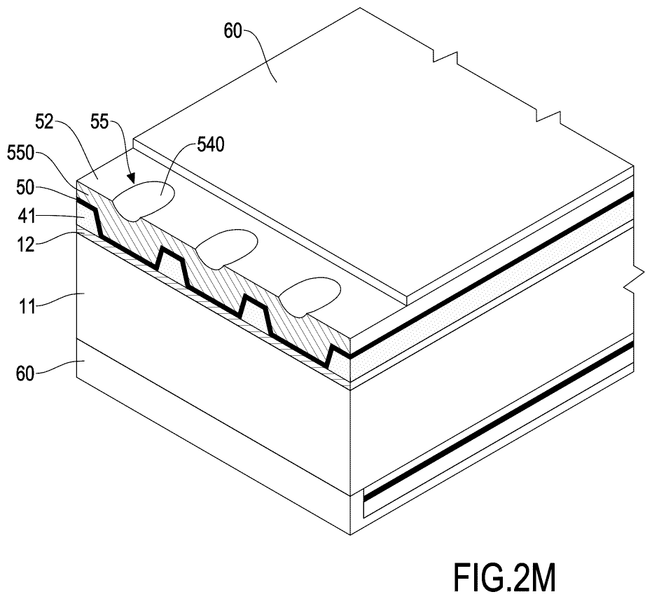

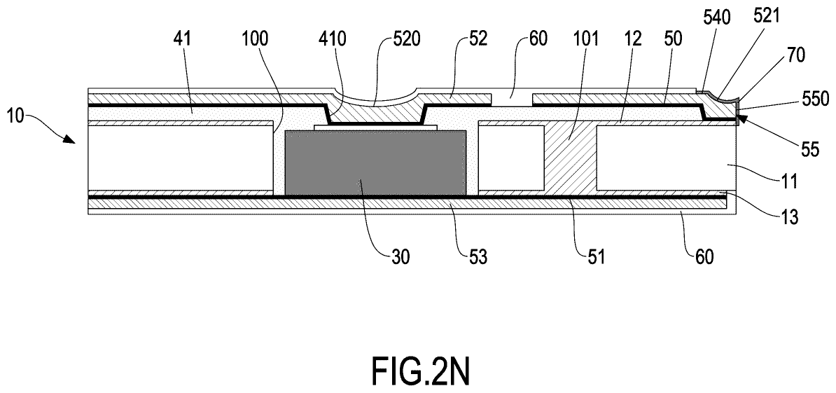

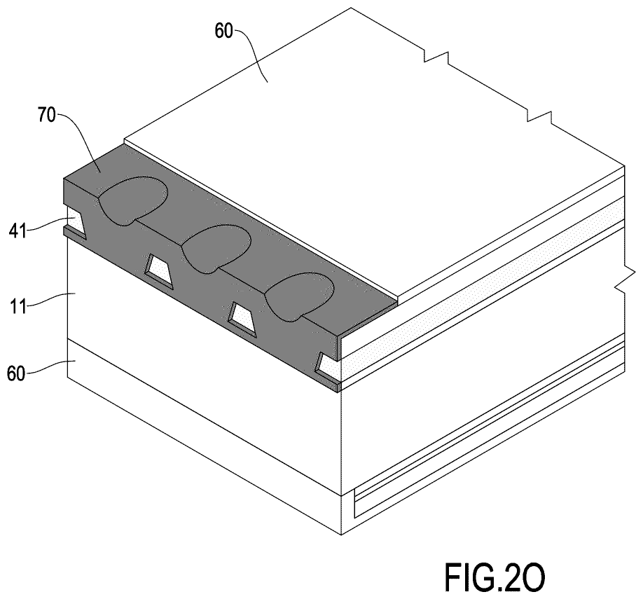

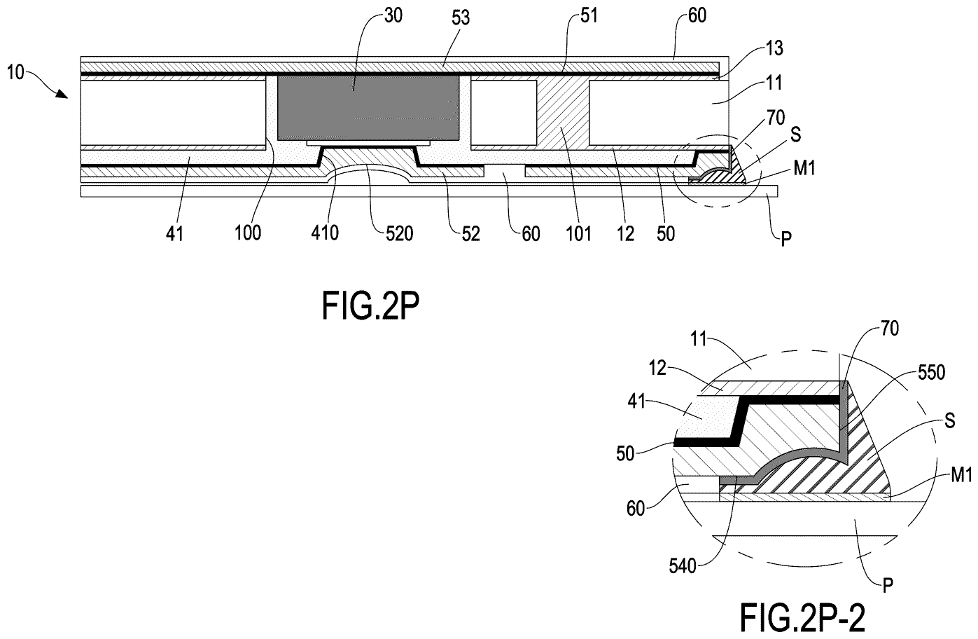

FIGS. 2A to 2N are schematic views of the packaging processes of a first embodiment of the package of the present invention. Referring to FIG. 2A, an accommodating space 100 is formed in the composite substrate 10. In particular, a semi-finished package in FIG. 2A is formed by multiple packing processes. Before forming the accommodating space 100, a drilling process can be performed on the composite substrate 10 to form at least one via, and then a metal deposition process can be performed on the top surface and the bottom surface of the composite substrate 10. A deposited metal M is deposited on an inner wall of the at least one via, so that the at least one via becomes the at least one conductive pillar 101, wherein the deposited metal M can be, for example, copper. During the metal deposition process, the deposited metal M deposited outside the composite substrate 10 and the upper metal sheet 11A and the lower metal sheet 11B form a conductive layer together. Specifically, the composite substrate 10 includes an upper conductive layer 12 and a lower conductive layer 13. The upper conductive layer 12 is located on a front surface of the composite substrate 10, and the upper conductive layer 12 is formed by the upper metal sheet 11A of the composite substrate 10 and the deposited metal M. The lower conductive layer 13 is located on a back surface of the composite substrate 10, and the lower conductive layer 13 is formed by the lower metal sheet 11B of the composite substrate 10 and the deposited metal M, wherein the upper conductive layer 12 is electrically connected to the lower conductive layer 13 through the at least one conductive pillar 101.

Moreover, a drilling process is performed on the composite substrate 10 formed with the at least one conductive pillar 101 to form the accommodating space 100 penetrating the composite substrate 10. Referring to FIG. 2B, an adhesive film 20 is attached to the lower conductive layer 13 to seal a bottom of the accommodating space 100. Referring to FIG. 2C, a die 30 is mounted on the adhesive film 20 and within the accommodating space 100. In particular, a bottom surface of the die 30 is fixed on the adhesive film 20, and a top surface and side surfaces of the die 30 are exposed from the accommodating space 100.

Referring to FIG. 2D, an insulating material 40 is placed on the composite substrate 10, and a lamination process is performed on the insulating material 40 to form a molding layer 41 as shown in FIG. 2E. The molding layer 41 covers the composite substrate 10 and fills the accommodating space 100 to wrap the die 30. In particular, the insulating material 40 will melt by heating into a semi-curing (flowable) state during the lamination process to flow and cover the surface of the composite substrate 10. The melted insulating material 40 also fills the accommodating space 100 of the composite substrate 10. The melted insulating material 40 will solidify to form the molding layer 41 after cooling. The die 30 is wrapped by the molding layer 41 and fixed in the accommodating space 100 of the composite substrate 10.

The next process is to form an upper redistribution layer (RDL) on the molding layer 41. The upper redistribution layer is electrically connected with the die 30 and the conductive layer of the composite substrate 10, and at least one conductive via is formed adjacent to at least one edge of the composite substrate 10. The at least one edge of the composite substrate 10 is at least one edge of the overall package, and the at least one edge of the composite substrate 10 refers to at least one side surface of the composite substrate 10 exposed by cutting during a subsequent singulation process. In the first embodiment of the present invention, each conductive via is a conductive blind via, fabrication steps of the upper redistribution layer and the said conductive blind via include the following steps shown in FIGS. 2F to 2J.

Referring to FIG. 2F, at least one die connecting via 410 and at least one substrate connecting via 411 are formed in the molding layer 41. For example, the at least one die connecting via 410 and the at least one substrate connecting via 411 are formed by a laser drilling process. The at least one die connecting via 410 exposes the top surface of the die 30, and the at least one substrate connecting via 411 exposes the conductive layer of the composite substrate 10. Referring to FIG. 2G, the adhesive film 20 attached to the lower conductive layer 13 is removed to expose the lower conductive layer 13 and the bottom of the accommodating space 100 (the bottom surface of the die 30).

Referring to FIG. 2H, an upper seed layer 50 is formed on the molding layer 41, the at least one die connecting via 410 and the at least one substrate connecting via 411. The upper seed layer 50 can be formed by plating, sputtering, etc., and the present invention is not limited to the foregoing examples. While forming the upper seed layer 50, a lower seed layer 51 can also be formed on a bottom surface of the lower conductive layer 13 and a bottom surface of the accommodating space 100 (the bottom surface of the die 30).

Referring to FIG. 2I, an upper metal layer 52 and a lower metal layer 53 are respectively formed on the upper seed layer 50 and the lower seed layer 51 by plating. That is, the upper seed layer 50 and the upper metal layer 52 are sequentially stacked on the molding layer 41, an inner wall of the at least one die connecting via 410 and an inner wall of the at least one substrate connecting via, and the lower seed layer 51 and the lower metal layer 53 are sequentially stacked on the bottom surface of the lower conductive layer 13. Positions on the top surface of the upper metal layer 52 corresponding to the at least one die connecting via 410 and the at least one substrate connecting via 411 relative to other areas on the top surface of the upper metal layer 52 to form a blind via respectively. Since an inner wall of each blind via is plated with metal (the upper metal layer 52), each blind via is a conductive blind via. The conductive blind via formed corresponding to the position of each die connecting via 410 is defined as an inside conductive blind via 520, and the conductive blind via formed corresponding to the position of each substrate connecting via 411 is defined as an edge conductive blind via 521. Each edge conductive blind via 521 is electrically connected with the conductive layer of the composite substrate 10, and each edge conductive blind via 521 is close to a cutting position of the subsequent singulation process relative to each inside conductive blind via 520.

Referring to FIG. 2J, a photo pattern PP can be disposed on the upper metal layer 52 and the lower metal layer 53 respectively, and the upper metal layer 52 and the lower metal layer 53 not covered by the photo pattern PP can be etched to make circuit distributions of the upper metal layer 52 and the lower metal layer 53 same as a shape of the photo pattern PP. Referring to FIG. 2K and FIG. 2K-2, the following packaging process is to remove the photo pattern PP and cover a solder mask 60 on the upper metal layer 52 and the lower metal layer 53 respectively. In particular, the upper metal layer 52 defines at least one surface bond pad 54. The at least one surface bond pad 54 is the area of the upper metal layer 52 (the upper redistribution layer) not covered by the solder mask 60, and the position of each surface bond pad 54 respectively corresponds to the position of the edge conductive blind via 521 formed by each substrate connecting via 411.

Referring to FIG. 2L and FIG. 2L-2, the singulation process is performed to form each individual package by cutting. In particular, the at least one surface bond pad 54 is arranged linearly. That is, the edge conductive blind via 521 formed by the at least one substrate via 411 is also arranged linearly. During the singulation process, an instrument cuts along the at least one surface bond pad 54 and cuts each edge conductive blind via 521 at the same time, wherein a top surface of a part of each surface bond pad 54 remaining in the package after cutting is defined as an edge bonding surface 540.

The part of each edge conductive blind via 521 remaining in the package after cutting is respectively defined as a conductive contact 55. Each conductive contact 55 is electrically connected with each edge bonding surface 540 and the conductive layer of the composite substrate 10 respectively. In the first embodiment of the present invention, each conductive contact 55 respectively is the surface bond pad 54 after cutting and is electrically connected to the upper conductive layer 12 of the composite substrate 10. Since the position of each surface bond pad 54 respectively corresponds to the position of the edge conductive blind via 521, a position of each edge bonding surface 540 respectively corresponds to a position of each conductive contact 55. Each edge bonding surface 540 is connected with a cutting surface 550 of each conductive contact 55.

In the present invention, each bonding surface 540 is a stepped surface. The stepped surface includes a flat surface and an arc-shaped concave surface. The flat surface extends from an edge of the solder mask 60 and connects with the arc-shaped concave surface. The arc-shaped concave surface is a top surface of the upper metal layer 52 in the edge conductive blind via 521, and the arc-shaped concave surface connects with a side surface (the cutting surface 550) of the conductive contact 55 corresponding to the edge bonding surface 540. Referring to FIG. 2M, the cutting surface 550 of the conductive contact 55 is a side surface of the upper redistribution layer, exposing the upper seed layer 50 and the upper metal layer 52.

Referring to FIG. 2N, an anti-oxidation conductive layer 70 is formed on each edge bonding surface 540, the cutting surface 550 of each conductive contact 55 and a side surface of the upper conductive layer 12. The anti-oxidation conductive layer 70 is a side-wettable flank, and material of the anti-oxidation conductive layer 70 can be metal such as tin, gold, etc., and the present invention is not limited to the foregoing examples. After completing the processes shown in FIGS. 2A to 2N, the first embodiment of the package with a side-wettable structure formed on via walls of the present invention (as shown in FIG. 2O) is formed. Referring to FIG. 2O, appearance features of the first embodiment of the present invention are as follows. The anti-oxidation layer 70 extends from at least one edge of the top surface of the package (the edge bonding surface 540) to at least one side surface of the package (the cutting surface 550 of the conductive contact 55 and the side surface of the upper conductive layer 12). Moreover, at least one side wall of the molding layer 41 and at least one side wall of the base layer 11 of the composite substrate 10 are unable to form the anti-oxidation layer 70, so that the at least one side wall of the molding layer 41 and the at least one side wall of the base layer 11 of the composite substrate 10 are uncovered by the anti-oxidation layer 70 and are exposed.

Referring to FIG. 2P and FIG. 2P-2, when the package of the present invention is soldered to a metal joint M1 of a circuit board P, the anti-oxidation conductive layer 70 can be adopted for a solder S adsorption, so that each surface bond pad 54 can be mounted on the circuit board P through the solder S and be electrically connected to the metal joint M1. The structure of the anti-oxidation layer 70 increases a contacting area between the solder S and each surface bond pad 54. Therefore, an Automated Optical Inspection instrument can photograph contacting situations between the package of the present invention and the circuit board P to determine whether the package is firmly soldered to the circuit board P.

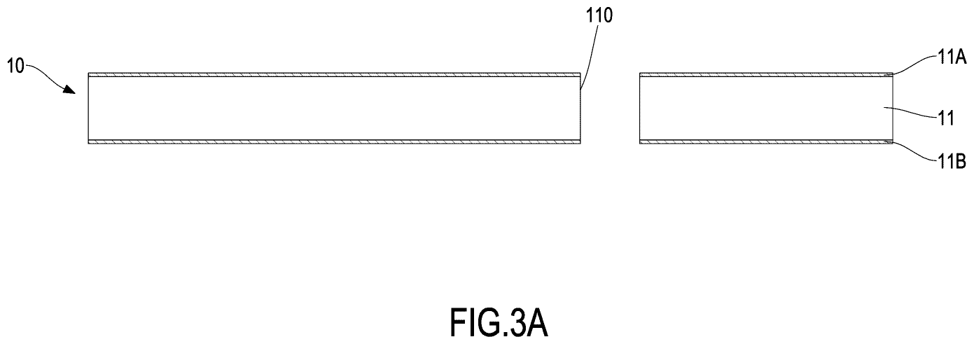

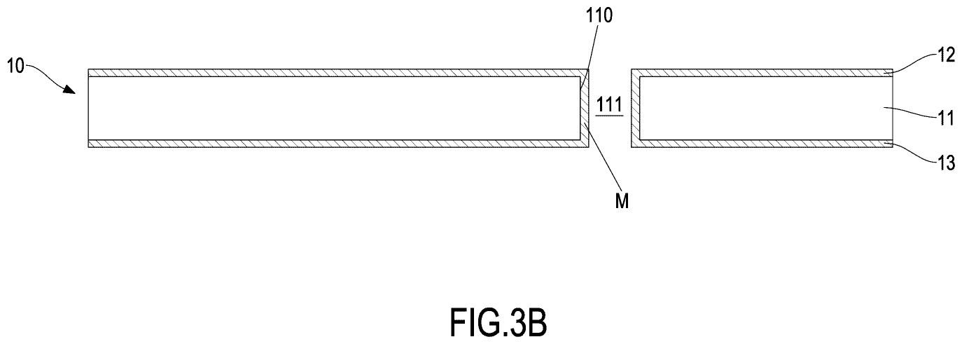

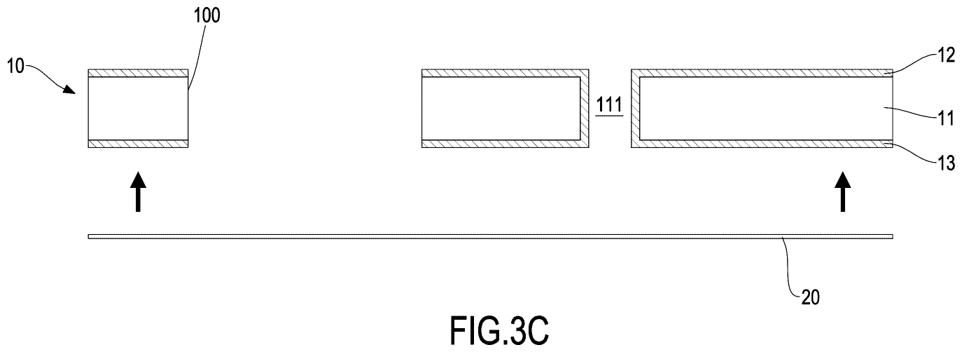

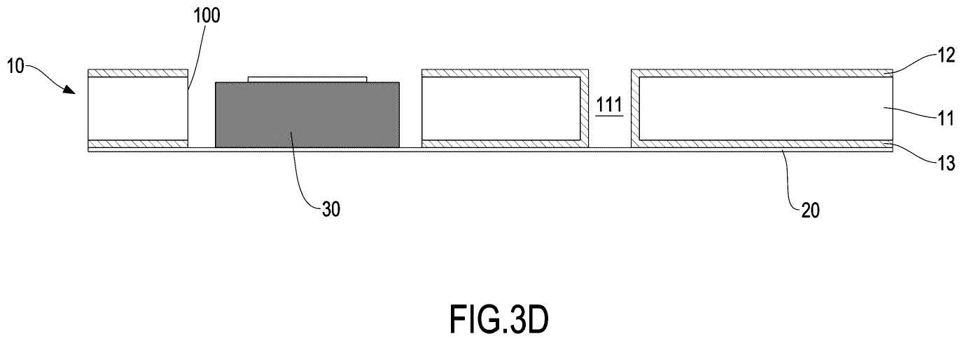

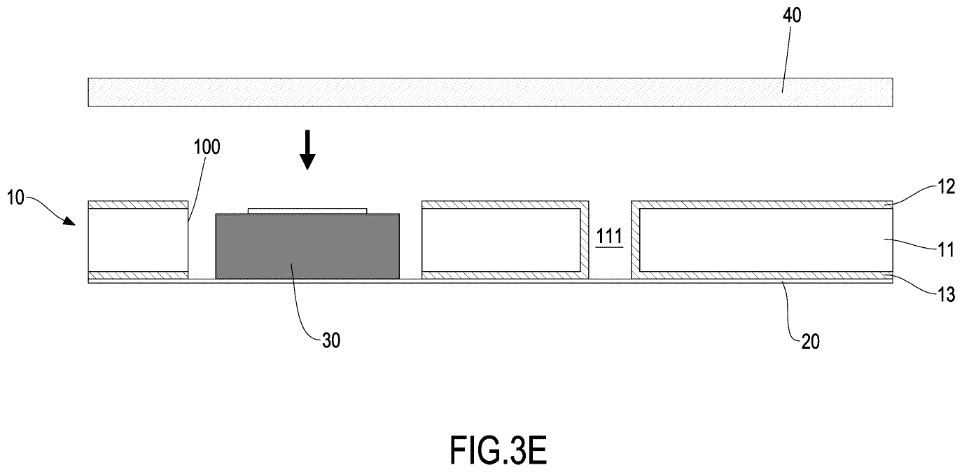

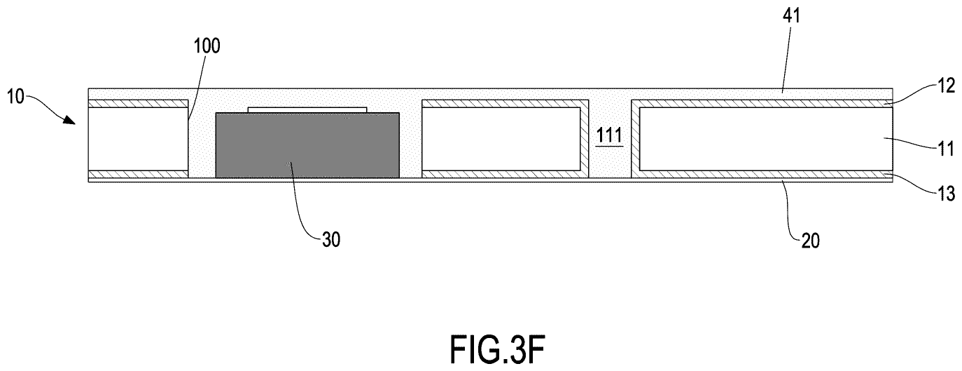

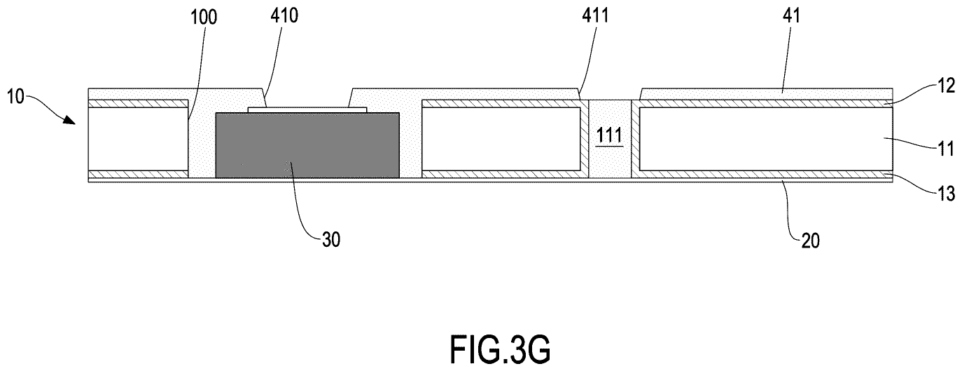

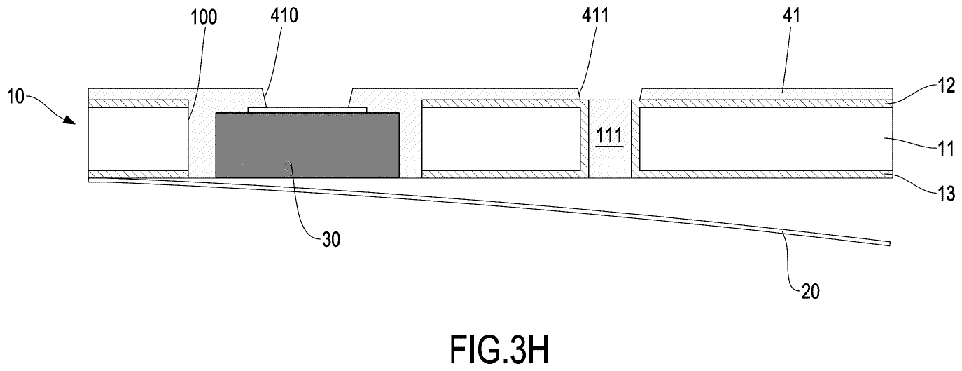

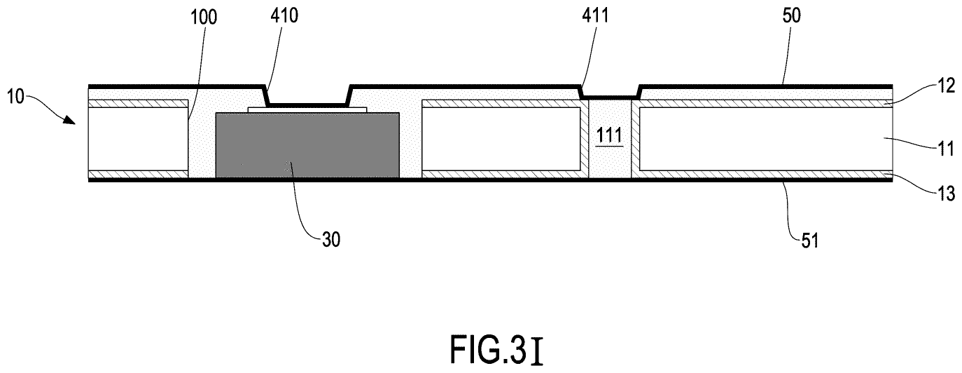

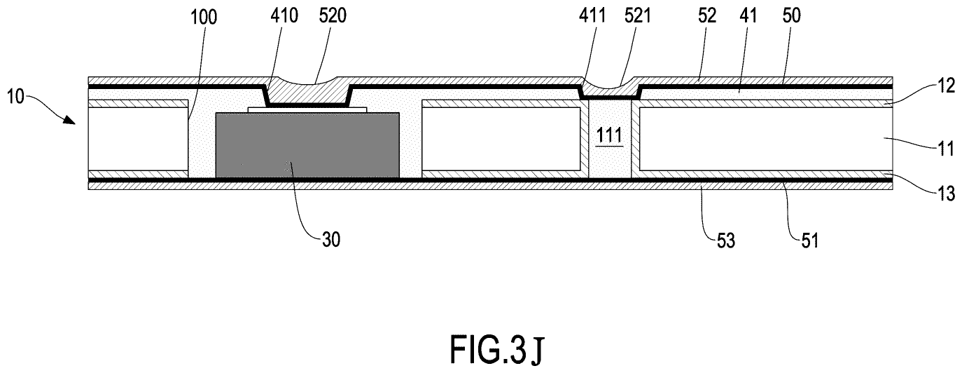

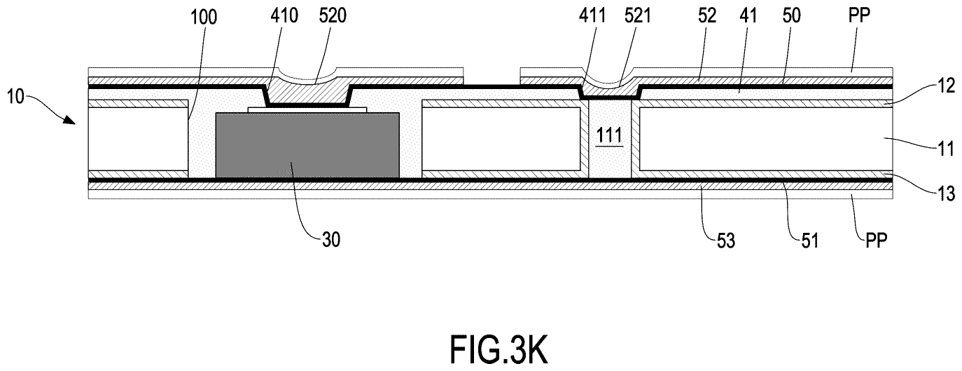

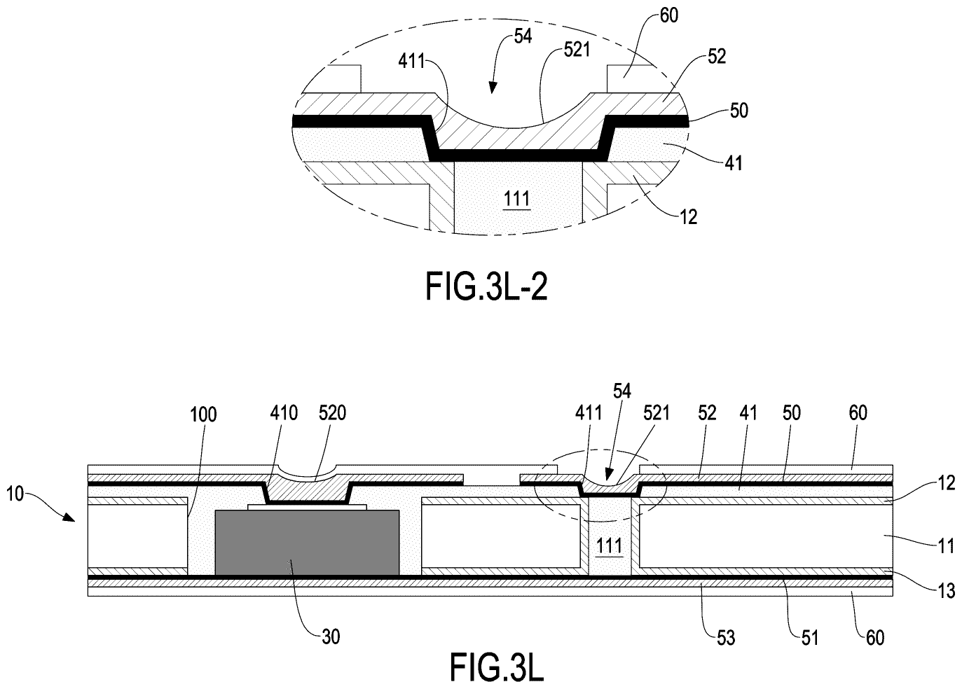

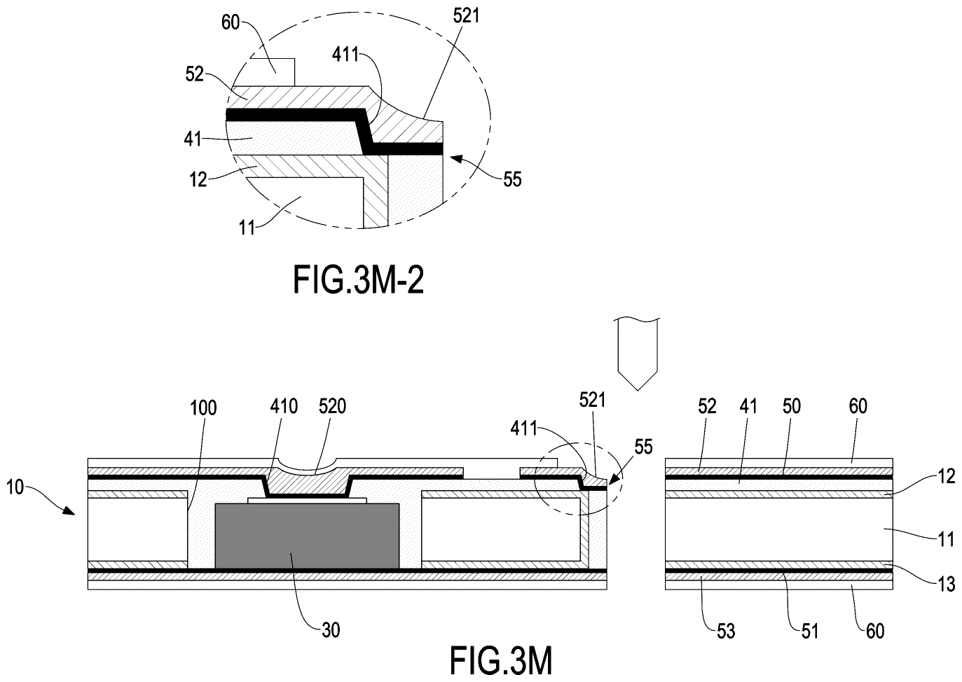

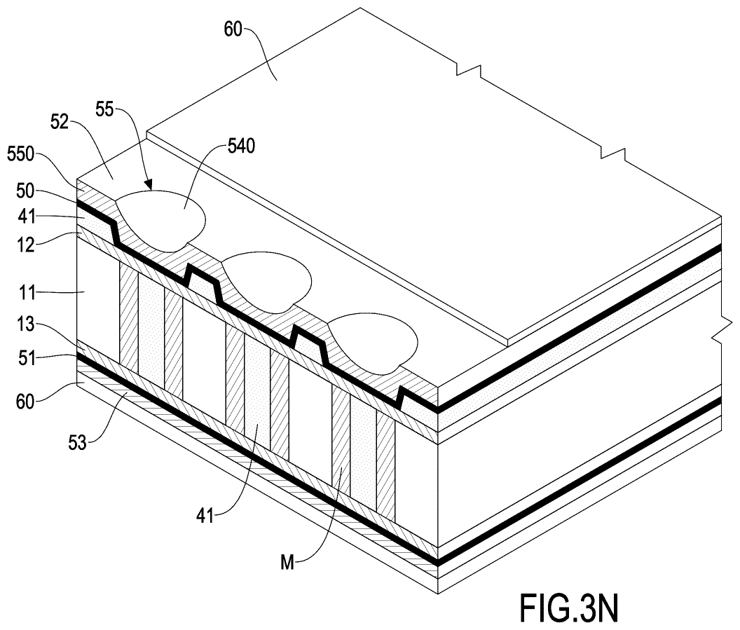

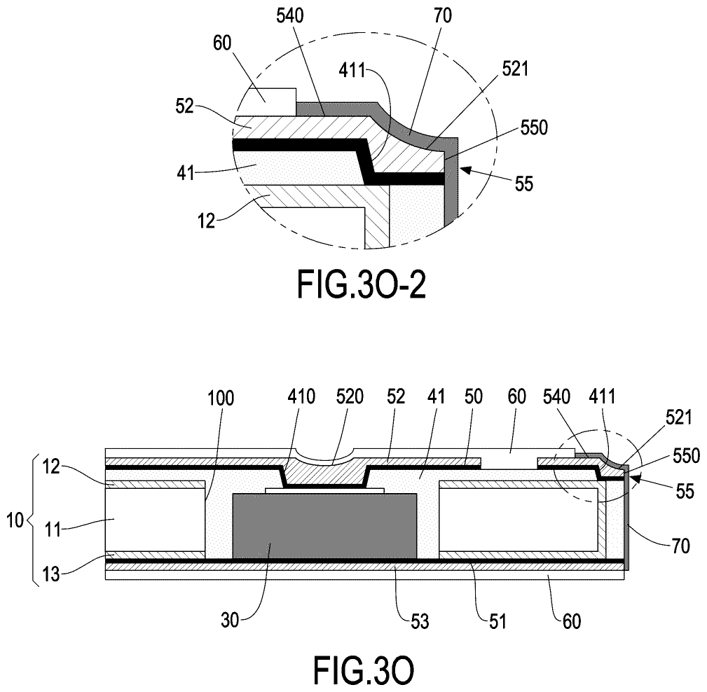

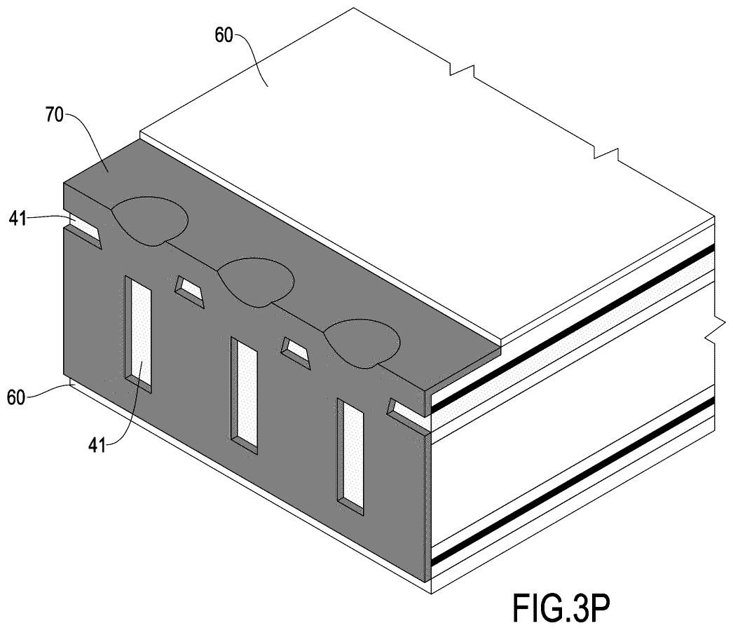

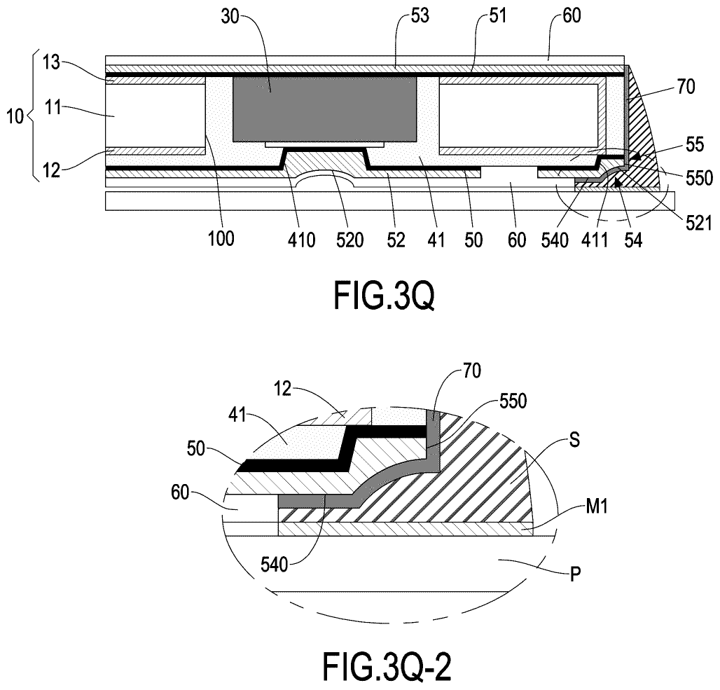

The package of the present invention also has a second embodiment. The second embodiment of the package is also formed by packaging the composite substrate 10 as shown in FIG. 1. Referring to FIGS. 3A to 3O, FIGS. 3A to 3O are schematic views of the packaging processes of the second embodiment of the package with a side-wettable structure formed on via walls of the present invention. A difference between the second embodiment and the first embodiment of the package of the present invention is that each conductive via in the second embodiment of the present invention includes an edge conductive blind via 521 and a plating via (plating through hole, PTH) 111.

Referring to FIGS. 3A to 3C, the drilling process is performed on the composite substrate 10 to form at least one via 110 before the accommodating space 100 being formed, wherein the at least one via 110 penetrates the composite substrate 10. The following process is to deposit the deposited metal M on the top surface and the bottom surface of the composite substrate 10. The deposited metal M is also deposited in each via 110, so that each via 110 becomes a plating via 111. The upper conductive layer 12 on the top surface of the composite substrate 10 and the lower conductive layer 13 on the bottom surface of the composite substrate 10 can be electrically connected by each plating via 111. Then, the drilling process is performed on the composite substrate 10 with the at least one plating via 111 to form the accommodating space 100 penetrating the composite substrate 10, and the adhesive film 20 is attached to the lower conductive layer 13 to seal the bottom of the accommodating space 100.

The subsequent manufacturing processes shown in FIGS. 3D to 3F are substantially same as the manufacturing processes of the first embodiment of the present invention. The subsequent manufacturing processes include mounting the die 30 in the accommodating space 100, placing the insulating material 40 on the composite substrate 10 and laminating the insulating material 40. A difference between the lamination process of the second embodiment and the lamination process of the first embodiment is as follows. In the lamination process of the second embodiment, the melted insulating material 40 not only fills the accommodating space 100 of the composite substrate 10 but also fills each plating via 111. After the melted insulating material 40 cools and solidifies, the molding layer 41 is formed in each plating via 111, and the die 30 is wrapped by the molding layer 41 and fixed in the accommodating space 100 of the composite substrate 10.

Referring to FIGS. 3G to 3K, the manufacturing processes to form the upper redistribution layer in the second embodiment of the present invention are substantially same as the manufacturing processes to form the upper redistribution layer in the first embodiment of the present invention. A difference between the said two manufacturing processes is as follows. As shown in FIG. 3G, during the manufacturing process to form the at least one die connecting via 410 and the at least one substrate connecting via 411 in the molding layer 41, the at least one substrate connecting via 411 exposes each plating via 111. That is, each substrate connecting via 411 is respectively connected with each plating via 111. The processes in FIGS. 3H to 3K are substantially same as the processes in FIGS. 2G to 2J. The processes in FIGS. 3H to 3K include removing the adhesive film 20, forming the upper seed layer 50 and the lower seed layer 51, forming the upper metal layer 52 and the lower metal layer 53 and deposing the photo pattern PP and etching, wherein a detail of each process is mentioned above and will not be described again. Please note that the position of the edge conductive blind via 521 formed by each substrate connecting via 411 corresponds to a position of each plating via 111 as shown in FIG. 3J.

Referring to FIG. 3L and FIG. 3L-2, the following packaging process is to remove the photo pattern PP and cover the solder mask 60 on the upper metal layer 52 and the lower metal layer 53 respectively to define the at least one surface bond pad 54. The position of each surface bond pad 54 respectively corresponds to the position of the edge conductive blind via 521 formed by each substrate connecting via 411 and the position of each plating via 111. Referring to FIG. 3M and FIG. 3M-2, during the singulation process, the instrument cuts along the at least one surface bond pad 54 and cuts each edge conductive blind via 521 and the plating via 111 corresponding to each edge conductive blind via at the same time, wherein the top surface of the part of each surface bond pad 54 remaining in the package after cutting is the edge bonding surface 540. In the second embodiment of the present invention, each bonding surface 540 is a stepped surface. The stepped surface includes a flat surface and an arc-shaped concave surface. The flat surface extends from an edge of the solder mask 60 and connects with the arc-shaped concave surface. The arc-shaped concave surface is a top surface of the upper metal layer 52 in the edge conductive blind via 521, and the arc-shaped concave surface connects with a side surface (the cutting surface 550) of the conductive contact 55 corresponding to the edge bonding surface 540.

The part of each edge conductive blind via 521 and each plating via 111 remaining in the package after cutting is respectively defined as a conductive contact 55. That is, a conductive contact 55 includes the part of an edge conductive blind via 521 remaining in the package after cutting and the part of a plating via 111 remaining in the package after cutting. Each conductive contact 55 is electrically connected with each edge bonding surface 540 and the conductive layer of the composite substrate 10 respectively. In particular, the part of each plating via 111 remaining in the package after cutting is respectively defined as an internal contact. Each internal contact is located in the composite substrate 10 and is electrically connected with the upper conductive layer 12 and the lower conductive layer 13. Referring to FIG. 3N, the cutting surface 550 of each conductive contact 55 includes a side surface of the upper redistribution layer (the upper seed layer 50 and the upper metal layer 52) and a side surface of the internal contact. Since each plating via 111 is filled with a part of the molding layer 41, the side surface of the internal contact exposes the molding layer 41 and the deposited metal M surrounding the molding layer 41.

Referring to FIG. 3O and FIG. 3O-2, the anti-oxidation conductive layer 70 is formed on each edge bonding surface 540, the cutting surface 550 of each conductive contact 55, the side surface of the upper conductive layer 12 and the side surface of the lower conductive layer 13 to complete the second embodiment of the package with a side-wettable structure formed on via walls of the present invention. Specifically, the anti-oxidation conductive layer 70 is formed on each edge bonding surface 540, the side surface of the upper redistribution layer, the deposited metal M of each internal contact, the side surface of the upper conductive layer 12 and the side surface of the lower conductive layer 13. Referring to FIG. 3P, appearance features of the second embodiment of the present invention are as follows. The anti-oxidation layer 70 extends from at least one edge of the top surface of the package (the edge bonding surface 540) to at least one side surface of the package (the cutting surface 550 of the conductive contact 55, the side surface of the upper conductive layer 12 and the side surface of the lower conductive layer 13). That is, the side surface formed during the singulation of the package is almost covered by the anti-oxidation conductive layer 70.

In addition, the at least one side wall of the molding layer 41 and the at least one side wall of the base layer 11 of the composite substrate 10 are unable to form the anti-oxidation layer 70, so that the at least one side wall of the molding layer 41 and the at least one side wall of the base layer 11 of the composite substrate 10 are uncovered by the anti-oxidation layer 70 and are exposed. The deposited metal M of the internal contact (formed by cutting the plating via 111) formed in the composite substrate is covered by the anti-oxidation conductive layer 70 and the molding layer surrounded by the deposited metal M is exposed. Therefore, the molding layer 41 can be seen as the side surface of the package formed in the singulation process between the adjacent base layers 11. That is, the side surface of each internal contact exposes the molding layer 41.

Referring to FIG. 3Q and FIG. 3Q-2, when the package of the present invention is soldered to the metal joint M1 of the circuit board P, the side surface formed during the singulation of the package is almost covered by the anti-oxidation conductive layer 70 for a solder S to adsorb, thereby increasing stability of the package soldered to the circuit board P and an inspection capability of the Automated Optical Inspection instrument. Moreover, the present invention has a third embodiment, which is also formed by packaging a composite substrate 10 similar to the composite substrate 10 as shown in FIG. 1, wherein a length of the composite substrate 10 of the third embodiment of the present invention is different from lengths of the first and second embodiments of the present invention.

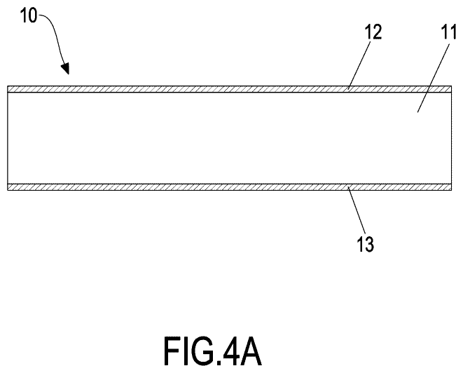

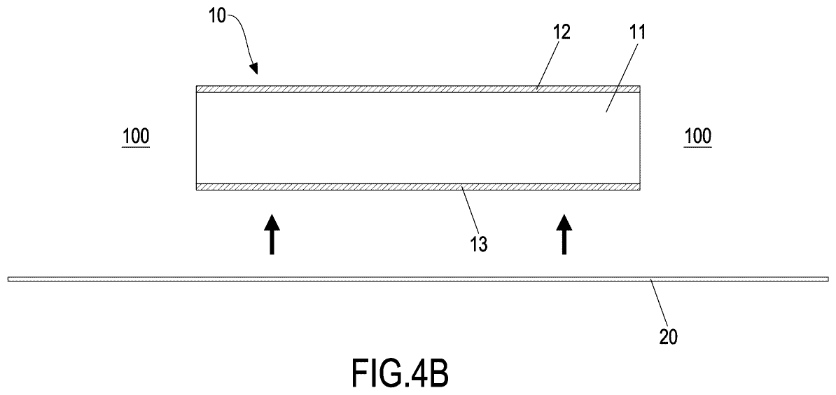

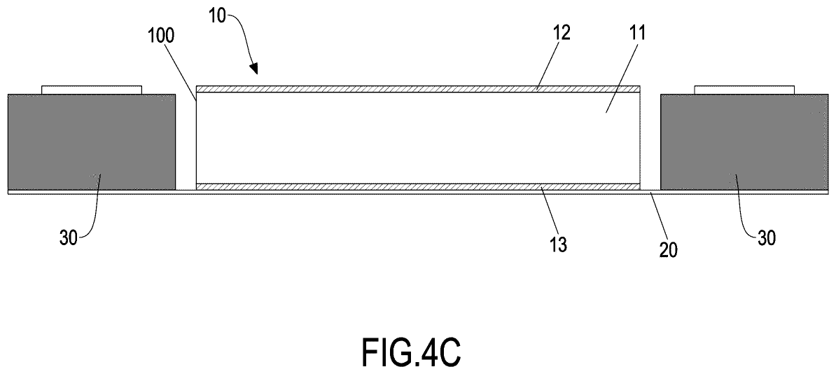

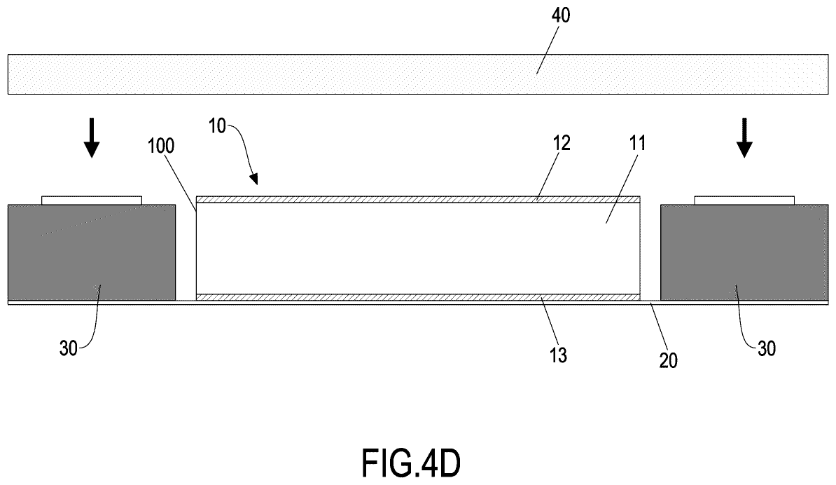

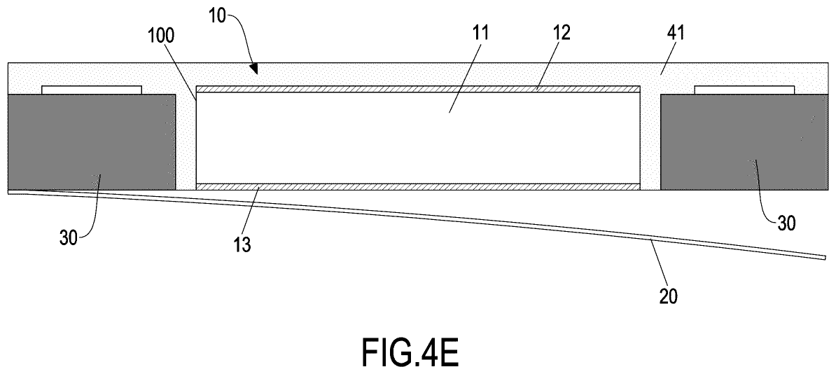

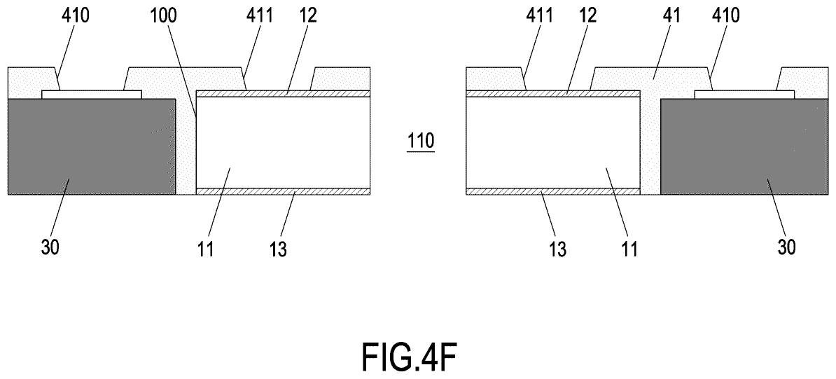

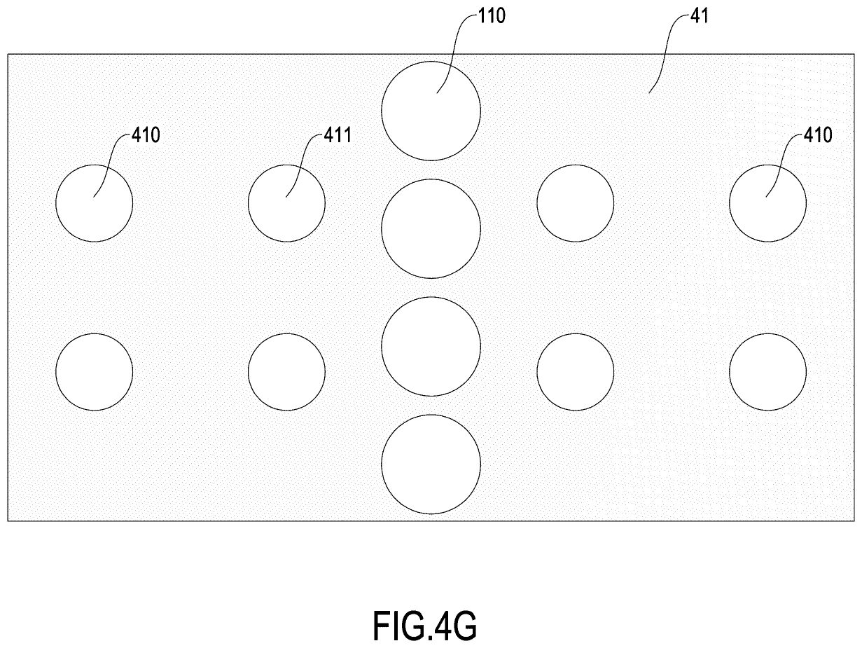

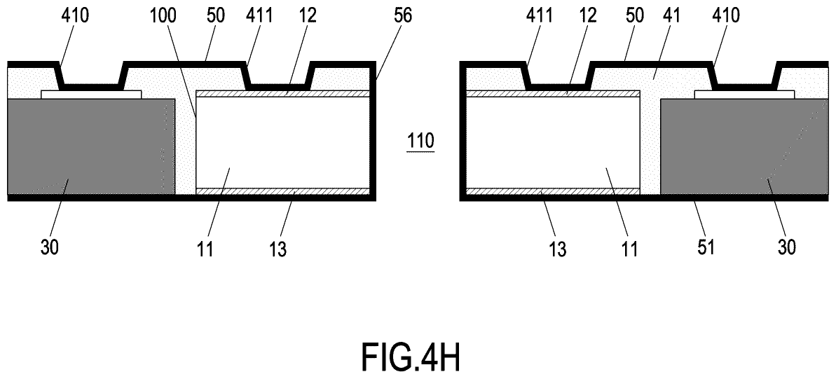

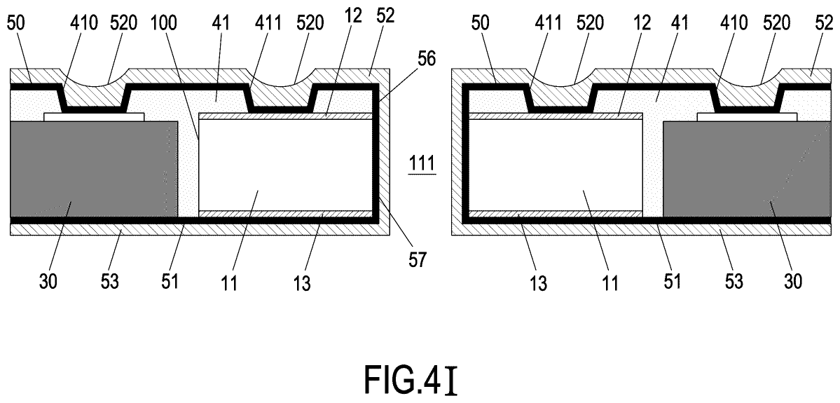

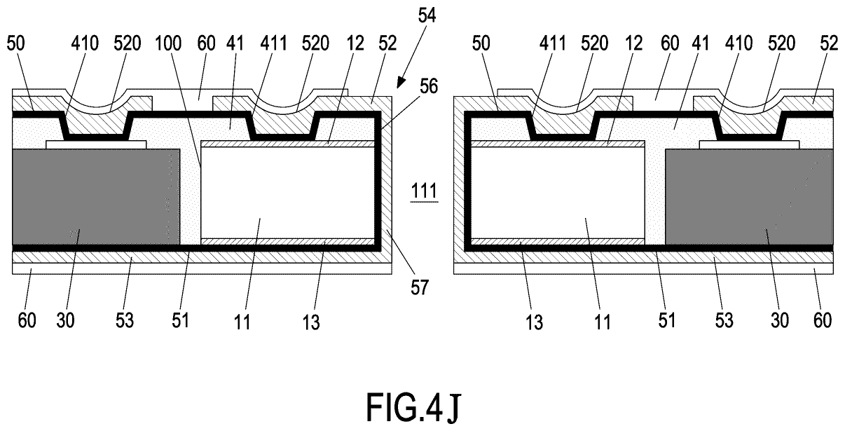

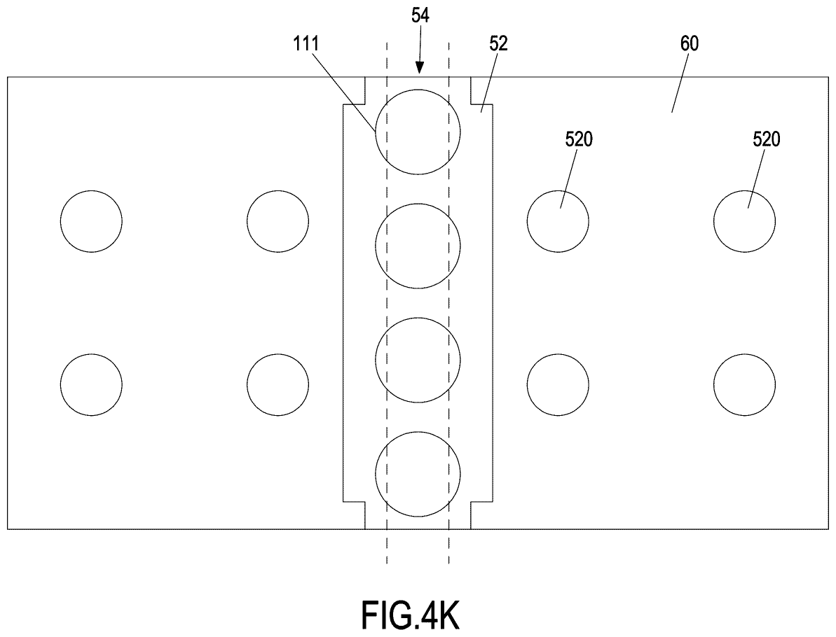

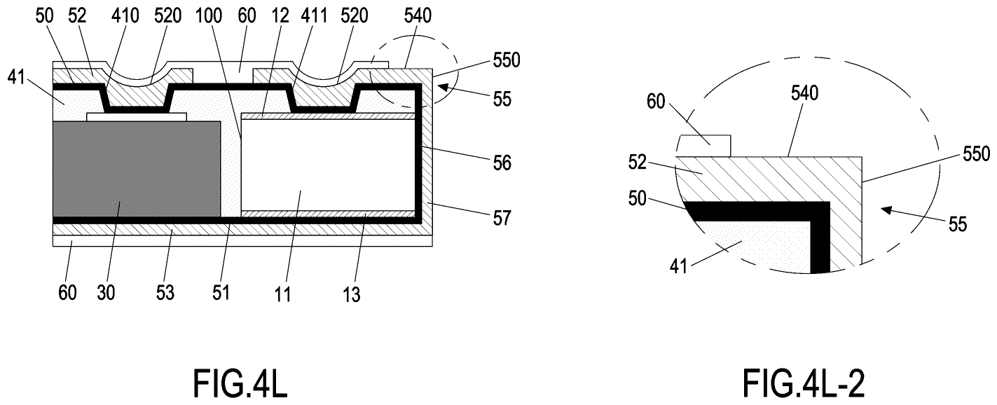

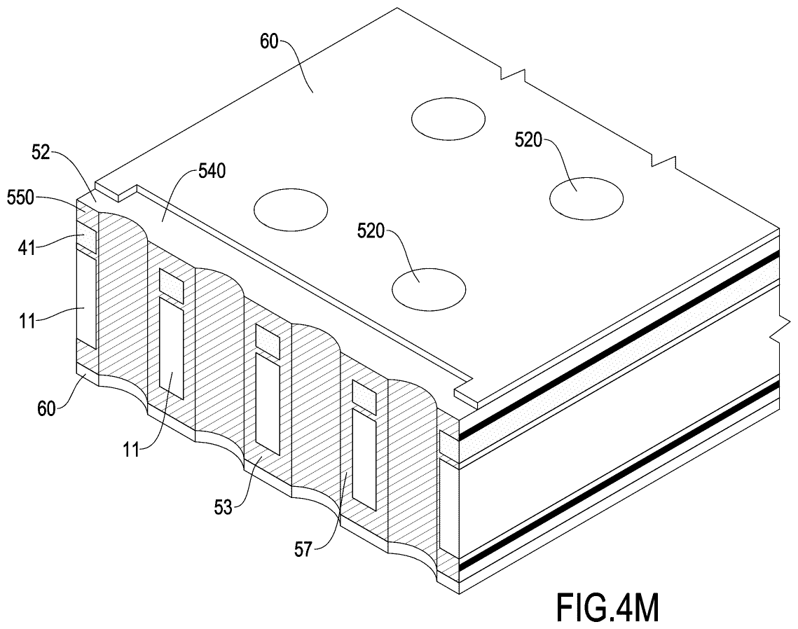

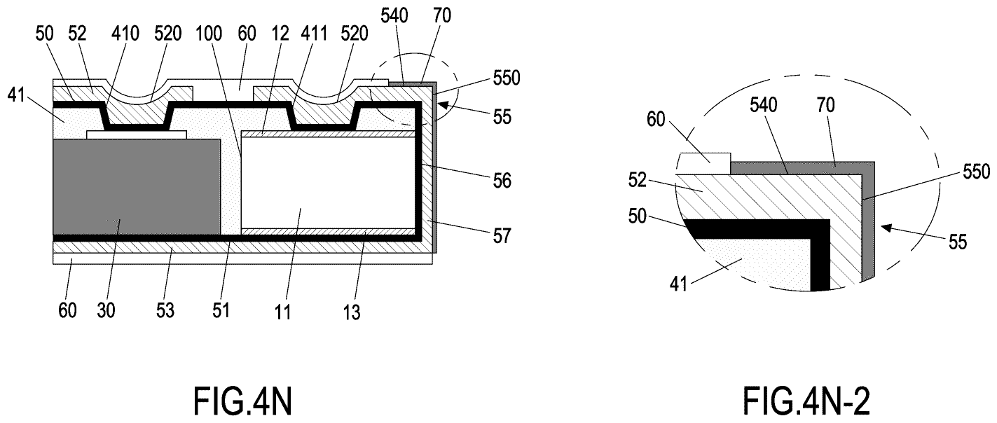

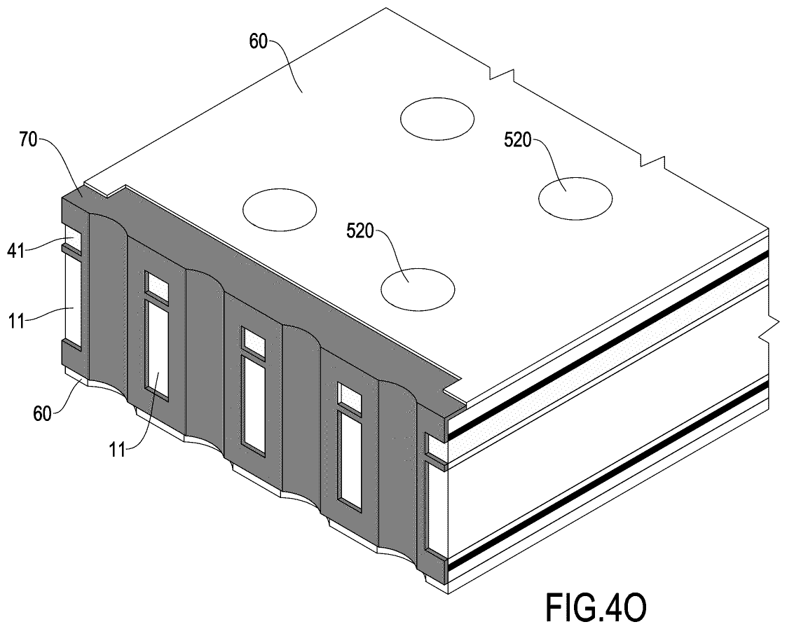

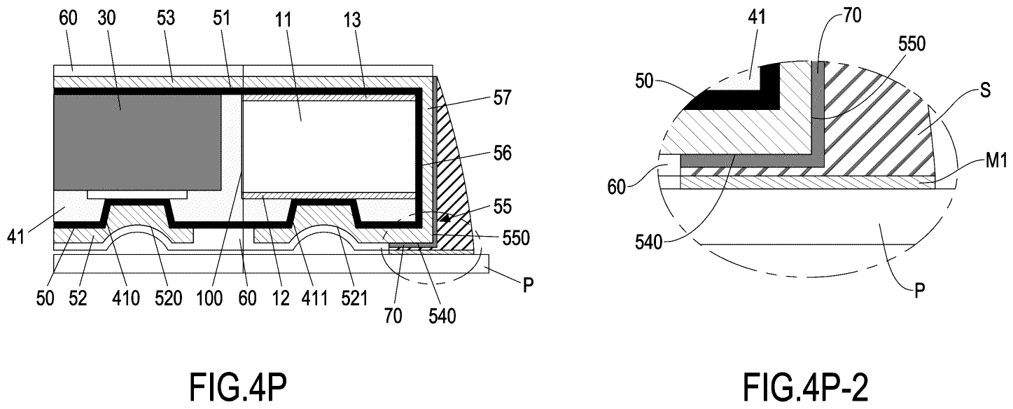

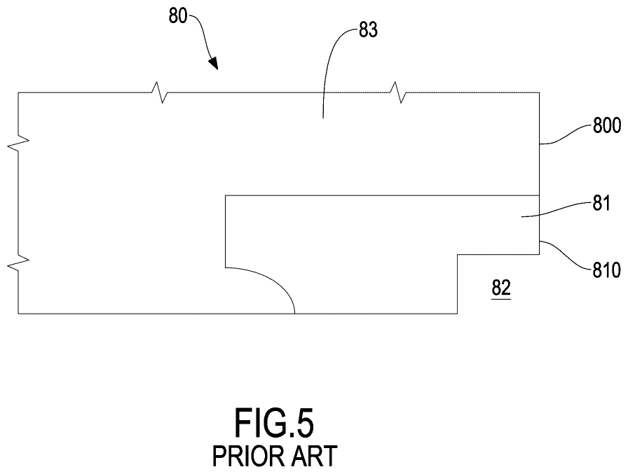

Referring to FIGS. 4A to 4N, FIGS. 4A to 4N are schematic views of the packaging processes of the third embodiment of the package with a side-wettable structure formed on via walls of the present invention. A difference between the third embodiment and the first and second embodiments of the package of the present invention is that each conductive via in the third embodiment of the present invention is respectively a plating via 111. The plating via 11 in the third embodiment of the present invention is formed after the molding layer 41 is formed.

Referring to FIGS. 4A to 4E, manufacturing processes before forming the molding layer 41 in the third embodiment of the present invention are substantially same as the manufacturing processes before forming the molding layer 41 in the first and the second embodiments of the present invention. The manufacturing processes before forming the molding layer 41 including depositing the metal on the composite substrate 10 to form the upper conductive layer 12 and the lower conductive layer 13, attaching the adhesive film 20 on the bottom surface of the composite substrate 10 to form the accommodating space (but not to form the at least one via 110), mounting the die 30 in the accommodating space 100, placing the insulating material 40 on the composite substrate 10 and laminating the insulating material 40 to form the molding layer 41, and removing the adhesive film 20, wherein the detail of each process is mentioned above and will not be described again.

Referring to FIGS. 4F and 4G, the at least one die connecting via 410 and the at least one substrate connecting via 411 are formed in the molding layer 41 by drilling. The at least one die connecting via 410 exposes the top surface of the die 30, and the at least one substrate connecting via 411 exposes the conductive layer of the composite substrate 10. The at least one via 110 is formed in the composite substrate 10 and the molding layer 41. A difference between the at least one via 110 in the third embodiment and the at least one via 110 in the second embodiment of the present invention is that the at least one via 110 in the third embodiment penetrates the molding layer 41 and the composite substrate 10. That is, the at least one via 110 communicates between the top surface of the molding layer 41 and the bottom surface of the composite substrate 10.

Referring to FIG. 4H, the upper seed layer 50 is formed on the composite layer 41, the at least one die connecting via 410 and the at least one substrate connecting via 411. The lower seed layer 51 is formed on the lower conductive layer 13 and the bottom surface of the accommodating space 100 (the bottom surface of the die 30), and an internal seed layer 56 is formed on the inner wall of each via, wherein the upper seed layer 50, the bottom seed layer 51 and the internal seed layer 56 are connected to each other. The internal seed layer 56, the upper seed layer 50 and the bottom seed layer 51 can be formed by plating, sputtering, etc., and the present invention is not limited to the foregoing examples.

Referring to FIG. 4I, the upper metal layer 52 and the lower metal layer 53 are respectively formed on the upper seed layer 50 and the bottom seed layer 51 by plating, so that the positions on the top surface of the upper metal layer 52 corresponding to the at least one die connecting via 410 and the at least one substrate connecting via 411 can form the blind via 520 respectively. An internal metal layer 57 is formed by depositing the metal on the internal seed layer 56 of each via 110, so that each via 110 respectively becomes a plating via 111. That is, the upper metal layer 52 can be electrically connected with the lower metal layer 53 by the plating via 111 (the internal metal layer 57). Moreover, each plating via 111 also electrically connects with the upper conductive layer 12 and the lower conductive layer 13 of the composite substrate 10. Since each plating via 111 in the third embodiment is formed after the molding layer 41 is formed, each plating via 111 in the third embodiment is not filled with a part of the molding layer 41.

Referring to FIG. 4J, the following packaging process is to cover the solder mask 60 on the upper metal layer 52 and the lower metal layer 53 respectively to define the at least one surface bond pad 54, wherein the position of each surface bond pad 54 respectively corresponds to the position of each plating via 111. Referring to FIG. 4K, during the singulation process, the instrument cuts along the at least one surface bond pad 54 and cuts the plating via 111 at the same time, wherein the top surface of the part of each surface bond pad 54 remaining in the package after cutting is defined as the edge bonding surface 540. In the third embodiment of the present invention, there is no corresponding conductive blind via 520 formed on each surface bond pad 54, so that each edge bonding surface 540 is a flat surface extending from the edge of the solder mask 60.

The part of each plating via 111 remaining in the package after cutting is respectively defined as a conductive contact 55. Since each plating via 111 is penetrated the molding layer 41 and the composite substrate 10, each conductive contact 55 extends from the surface bond pad 54 to the lower conductive layer 13 of the composite substrate 13. Each conductive contact 55 includes two parts. The conductive contact 55 extends from the surface bond pad 54 to the composite substrate 10 is defined as a connecting contact, and the conductive contact 55 located in the composite substrate 10 to electrically connect with the upper conductive layer 12 and the lower conductive layer 13 is defined as an internal contact, and each connecting contact is respectively connected with the corresponding internal contact. Referring to FIG. 4L, FIG. 4L-2 and FIG. 4M, the cutting surface 550 of each conductive contact 55 is respectively connected with the corresponding edge bonding surface 540, and the cutting surface 550 of each conductive contact 55 includes the side surface of the upper redistribution layer (the surface bond pad 54), the side surface of the connecting contact and the side surface of the internal contact.

Referring to FIG. 4N and FIG. 4N-2, the anti-oxidation conductive layer 70 is formed on each edge bonding surface 540, the cutting surface 550 of each conductive contact 55, the side surface of the upper conductive layer 12 and the side surface of the lower conductive layer 13 to complete the third embodiment of the package with a side-wettable structure formed on via walls of the present invention. Referring to FIG. 4O, the appearance features of the third embodiment of the present invention are as follows. The anti-oxidation layer 70 extends from at least one edge of the top surface of the package (the edge bonding surface 540) to at least one side surface of the package (the cutting surface 550 of the conductive contact 55, the side surface of the upper conductive layer 12 and the side surface of the lower conductive layer 13). That is, the side surface formed during the singulation of the package is almost covered by the anti-oxidation conductive layer 70.

A difference between the appearance features of the third embodiment and the appearance features of second embodiment of the present invention is that each edge bonding surface 540 in the third embodiment is a flat surface. Since each plating via 111 is not filled with a part of the molding layer 41, regions between the adjacent base layers 11 on the side surface formed by cutting the package (the side surface of the internal contact) is covered by the anti-oxidation conductive layer 70 without exposing the molding layer 41. Referring to FIG. 4P and FIG. 4P-2, when the package of the third embodiment of the present invention is soldered to the metal joint M1 of the circuit board P, the side surface formed during the singulation of the package is almost covered by the anti-oxidation conductive layer 70 for the solder S to adsorb, thereby increasing the stability of the package soldered to the circuit board P and the inspection capability of the Automated Optical Inspection instrument.

During the manufacturing processes of the package with a side-wettable structure formed on via walls of the present invention, the at least one conductive via connecting with the upper redistribution layer and the conductive layer of the composite substrate 10 is located adjacent to at least one edge of the entire package, so that the at least one conductive via can be cut during the singulation process of the package. The part of each conductive via remaining in the package after cutting is respectively defined as a conductive contact 55. Since the cutting surface 550 by singulation process of each conductive contact 55 exposes a metal layer, the anti-oxidation conductive layer 70 can be plated on the cutting surface of each conductive contact 55 to form the side-wettable structure. Compared with the prior art that the lead frame needs to be pre-processed before the manufacturing processes (or need to be cut multiple times during the manufacturing processes) to form the side-wettable structure, a structural improvement of the package of the present invention can form the side-wettable structure through only one cutting (singulation process), thereby reducing process complexity and saving manufacturing costs.

The anti-oxidation conductive layer 70 is adopted for a solder S adsorption, and the side surface of each conductive contact 55 can be the anti-oxidation conductive layer 70 to be plated on. The anti-oxidation conductive layer 70 mounted on the surface of each conductive contact 55 increases an area to which the solder S adheres when the package of the present invention is soldered to another component, thereby increasing the stability of the package soldered to the circuit board P. Moreover, the side surface of the package of the present invention can be adhered with more solder S compared with the prior art to improve the inspection capability of the Automated Optical Inspection instrument, so that the present invention has an effect of stabilizing the automated manufacturing process.

The above only records the implementations or embodiments of the technical artifices adopted by the present invention to solve the problems, and is not configured to limit the claims of the present invention. That is, all equivalent changes and modifications that are consistent with the meaning of the claims of the present invention or made in accordance with the claims of the present invention are covered by the claims of the present invention.

What is claimed is:

1. A package with a side-wettable structure formed on via walls, comprising:
a composite substrate having a conductive layer on an exterior of the composite substrate and an accommodating space in an interior of the composite substrate;
a die mounted in the accommodating space;
a molding layer covering the composite substrate and filling the accommodating space to wrap the die;
an upper redistribution layer mounted on the molding layer;
a solder mask covering the upper redistribution layer and exposing at least one edge of the upper redistribution layer to form at least one edge bonding surface; and
at least one conductive contact formed by cutting at least one conductive via and located adjacent to at least one edge of the composite substrate, and each conductive contact correspondingly and electrically connected with each edge bonding surface and the conductive layer of the composite substrate respectively;
wherein each conductive contact comprises a cutting surface including a side surface of the upper redistribution layer and connected with the at least one edge bonding surface, and an anti-oxidation conductive layer is mounted on each bonding surface and the cutting surface of each conductive contact.

2. The package as claimed in claim 1, wherein
each edge bonding surface is a stepped surface comprising a flat surface and an arc-shaped concave surface;
the flat surface extends from an edge of the solder mask and connects with the arc-shaped concave surface; and
the arc-shaped concave surface connects with the cutting surface of the conductive contact corresponding to the edge bonding surface.

3. The package as claimed in claim 2, wherein
the conductive layer of the composite substrate comprises an upper conductive layer located on a top surface of the composite substrate and electrically connects with each conductive contact; and
the anti-oxidation conductive layer is mounted on the cutting surface of each conductive contact and a side surface of the upper conductive layer.

4. The package as claimed in claim 2, wherein
the conductive layer of the composite substrate comprises an upper conductive layer located on a top surface of the composite substrate and a lower conductive layer located on a bottom surface of the composite substrate;
each conductive contact comprises an internal contact formed in the composite substrate and electrically connecting with the upper conductive layer and the lower conductive layer;
the cutting surface of each conductive contact comprises a side surface of the internal contact; and
the anti-oxidation conductive layer is mounted on the side surface of the upper redistribution layer, and on metal on the side surface of each internal contact, a side surface of the upper conductive layer, and a side surface of the lower conductive layer.

5. The package as claimed in claim 4, wherein
each internal contact comprises the molding layer and a deposited metal; and
the side surface of each internal contact exposes the molding layer and the deposited metal surrounding the molding layer.

6. The package as claimed in claim 1, wherein
each edge bonding surface is a flat surface extending from an edge of the solder mask;
the conductive layer of the composite substrate comprises an upper conductive layer located on a top surface of the composite substrate and a lower conductive layer located on a bottom surface of the composite substrate;
each conductive contact comprises an internal contact formed in the composite substrate and electrically connecting with the upper conductive layer and the lower conductive layer;
the cutting surface of each conductive contact comprises a side surface of the internal contact; and
the anti-oxidation conductive layer is mounted on the cutting surface of each conductive contact, a side surface of the upper conductive layer, and a side surface of the lower conductive layer.

7. The package as claimed in claim 1, wherein
the upper redistribution layer comprises an upper seed layer and an upper metal layer sequentially stacked on the molding layer;
each conductive via is an edge conductive blind via formed by the upper seed layer and the upper metal layer;
each edge bonding surface comprises a top surface of the upper metal layer in each edge conductive blind via; and
the top surface of the upper metal layer in each edge conductive blind via is an arc-shaped concave surface.

8. The package as claimed in claim 1, wherein
the upper redistribution layer comprises an upper seed layer and an upper metal layer sequentially stacked on the molding layer;
each conductive via comprises an edge conductive blind via and a plating via;
a position of each edge conductive blind via corresponds to a position of each plating via;
each edge conductive blind via is formed by the upper seed layer and the upper metal layer;
each plating via is filled with a part of the molding layer;
each edge bonding surface comprises a top surface of the upper metal layer in each edge conductive blind via; and
the top surface of the upper metal layer in each edge conductive blind via is an arc-shaped concave surface.

9. The package as claimed in claim 1, wherein
each conductive via is a plating via; and
each plating via is formed by a via located in the composite substrate and the molding layer.

10. The package as claimed in claim 1, wherein each edge bonding surface is a top surface of a part of a surface bond pad remaining in the package after cutting.
